(19) United States
(12) Patent Application Publication
(10) Pub. No.: US 2024/0264344 A1
(43) Pub. Date: Aug. 8, 2024

(54) COLOR FILM SUBSTRATE AND METHOD OF MANUFACTURING THE SAME, DISPLAY SUBSTRATE AND METHOD OF MANUFACTURING THE SAME, AND DISPLAY DEVICE

(71) Applicant: BOE Technology Group Co., Ltd., Beijing (CN)

(72) Inventors: Xiang Li, Beijing (CN); Shi Shu, Beijing (CN); Yong Yu, Beijing (CN); Chuanxiang Xu, Beijing (CN); Yang Yue, Beijing (CN); Xiao Zhang, Beijing (CN); Mingxing Wang, Beijing (CN); Wei Li, Beijing (CN); Wei He, Beijing (CN); Haowei Zou, Beijing (CN); Qi Yao, Beijing (CN)

(73) Assignee: BOE Technology Group Co., Ltd., Beijing (CN)

(21) Appl. No.: 18/021,688

(22) PCT Filed: Mar. 1, 2022
(86) PCT No.: PCT/CN2022/078675

§ 371 Date: Feb. 16, 2023

(51) Int. Cl. G02B 5/20

(52) U.S. Cl. CPC G02B 5/201

(57) ABSTRACT

A color film substrate and a method of manufacturing the same, a display substrate and a method of manufacturing the same and a display device are provided. The color film substrate includes: a base substrate; a plurality of pixel units arranged on the base substrate, each unit includes a plurality of sub-pixels; the pixel unit includes: a barrier including a first barrier arranged around a peripheral side of the pixel unit and a second barrier arranged between adjacent sub-pixels, and the plurality of sub-pixels include a first sub-pixel for color conversion and a second sub-pixel for scattering; a color conversion material layer arranged in the first sub-pixel; a scattering material layer arranged in the second sub-pixel; at least one of the first barrier and the second barrier is in a same layer as the scattering material layer (50), and has the same material as that of the scattering material layer.

### TECHNICAL FIELD

The present disclosure relates to a field of display technology, in particular to a color filmi substrate and a method of manufacturing the color film substrate, a display substrate and a method of manufacturing the display substrate, and a display device.

### BACKGROUND

A color conversion scheme of zoned miniature inorganic light-emitting diode is to use a zoned blue light-emitting diode scheme to zone a large blue light-emitting diode into a plurality of small light-emitting diodes, which may be controlled independently, thus reducing a number of keystrokes and reducing a cost. In addition, since an efficiency of a conventional red chip is significantly reduced after miniaturization, a blue light plus color conversion scheme may be used to improve a luminous efficiency of a device. However, a preparation of color conversion chip needs to align a color film substrate with a light-emitting element. A design problem of the color film substrate causes that a bonding adhesive is thicker in bonding, which increases a distance between a color conversion layer and a light-emitting region in the color film substrate, which tends to cause a color crossover. Schemes to reduce a risk of color crossover in related technologies mainly include changing a refractive index of each film layer or making a lens structure. The scheme of changing the refractive index of the film layer needs to redevelop for each film layer, which increases a difficulty of development. A thickness of the lens structure is high, which is not conducive to a thinning of the device.

It should be noted that the information disclosed in the above background technology part is only used to strengthen the understanding of the background of the present disclosure, so it may include information that does not constitute the existing technologies known to those skilled in the art.

### SUMMARY

In one aspect, there is provided a color film substrate, including:
a base substrate;
a plurality of pixel units arranged on the base substrate, wherein each of the plurality of pixel units includes a plurality of sub-pixels;
wherein the pixel unit includes:
a barrier arranged on a side of the base substrate, wherein the barrier includes a first barrier arranged around a peripheral side of the pixel unit and a second barrier arranged between adjacent sub-pixels, and the plurality of sub-pixels inchide a first sub-pixel for color conversion and a second sub-pixel for scattering;
a color conversion material layer arranged in the first sub-pixel;
a scattering material layer arranged in the second sub-pixel;
wherein at least one of the first barrier and the second barrier is in a same layer as the scattering material layer, and a material of the at least one of the first barrier and the second barrier is the same as a material of the scattering material layer.

In some exemplary embodiments of the present disclosure, in a direction perpendicular to a direction of a plane on which the base substrate is located, a side of the first barrier away from the base substrate has a first distance to the base substrate, a side of the second barrier away from the base substrate has a second distance to the base substrate, and the first distance is greater than the second distance.

In some exemplary embodiments of the present disclosure, the pixel unit includes two or more first sub-pixels,
in the direction perpendicular to the direction of the plane on which the base substrate is located, a side of the second barrier between adjacent first sub-pixels away from the base substrate has a first sub-distance to the base substrate, and a side of the second barrier between adjacent first sub-pixel and second sub-pixel away from the base substrate has a second sub-distance to the base substrate,
wherein the first sub-distance is greater than the second sub-distance.

In some exemplary embodiments of the present disclosure, a size of at least one boundary of a section of at least one of the first barrier and the second barrier is greater than a size of a thickness of the scattering material layer, and the section is parallel to a direction of a plane on which the base substrate is located.

In some exemplary embodiments of the present disclosure, a size of at least one boundary of a section of at least one of the first barrier and the second barrier is greater than or equal to a thickness of the first barrier and/or the second barrier in a direction perpendicular to a direction of a plane on which the base substrate is located, and the section is parallel to the direction of the plane on which the base substrate is located.

In some exemplary embodiments of the present disclosure, a thickness of the scattering material layer is less than a thickness of the color conversion material layer in a direction perpendicular to a direction of a plane on which the base substrate is located.

In some exemplary embodiments of the present disclosure, the color film substrate further includes:
a black matrix arranged between the base substrate and the barrier, and the black matrix including a plurality of openings corresponding to the plurality of sub-pixels;
a color film layer including a first color film part and a second color film part;
wherein an orthographic projection of the first color film part on the base substrate is located in the opening;
an orthographic projection of the second color film part on the base substrate is located within an orthographic projection of the black matrix on the base substrate.

In some exemplary embodiments of the present disclosure, the first sub-pixel includes a first color sub-pixel and a third color sub-pixel, the second sub-pixel includes a second color sub-pixel, the first color sub-pixel and the third color sub-pixel are located in the first sub-pixel, and the second color sub-pixel is located in the second sub-pixel.

In some exemplary embodiments of the present disclosure, the first color film part includes:
a first color filter layer disposed in the first color sub-pixel and a third color filter layer disposed in the third color sub-pixel.

In some exemplary embodiments of the present disclosure, the first color film part includes:
a second color filter layer disposed in the second color sub-pixel.

In some exemplary embodiments of the present disclosure, a thickness of the second color film part is greater than a thickness of the first color film part in a direction perpendicular to a direction of a plane on which the base substrate is located.

In some exemplary embodiments of the present disclosure, the second color film part includes at least two stacked filter layers.

In some exemplary embodiments of the present disclosure, an optical density of a material of the barrier is in a range of 0.1/um to 0.3/um.

In some exemplary embodiments of the present disclosure, the color conversion material layer includes a quantum dot material.

In some exemplary embodiments of the present disclosure, the color film substrate further includes:
an encapsulation layer arranged on a side of the barrier away from the base substrate, and the encapsulation layer covering at least one of the barrier, the color conversion material layer and the scattering material layer.

In another aspect of the present disclosure, there is provided a display substrate, including:
the color film substrate as described above;
a light-emitting element arranged on a side of the color filmi substrate away from the base substrate; and
a bonding material layer arranged between the color film substrate and the light-emitting element.

In some exemplary embodiments of the present disclosure, the light-emitting element includes MicroLED or OLED.

In some exemplary embodiments of the present disclosure, the bonding material layer has a first thickness between a color conversion material layer of the color film substrate and the light-emitting element,
the bonding material layer has a second thickness between a scattering material layer of the color film substrate and the light-emitting element.
the first thickness is less than the second thickness.

In another aspect of the present disclosure, there is provided a method of manufacturing a color film substrate, including:
forming a base substrate;
forming a plurality of pixel units on the base substrate, wherein each of the plurality of pixel units includes a plurality of sub-pixels;
wherein forming the pixel unit includes:
forming a barrier on a side of the base substrate, wherein forming the barrier includes forming a first barrier arranged around a peripheral side of the pixel unit and forming a second barrier arranged between adjacent sub-pixels, and the plurality of sub-pixels include a first sub-pixel for color conversion and a second sub-pixel for scattering:
forming a color conversion material layer in the first sub-pixel;
forming a scattering material layer in the second sub-pixel;
wherein the scattering material layer and the barrier are formed by a one-time patterning process.

In yet aspect of the present disclosure, there is provided a method of manufacturing a display substrate, including:
forming a color film substrate according to the manufacturing method described above;
forming a bonding adhesive on a side of a color conversion material layer of the color film substrate away from a base substrate, wherein the bonding adhesive is located in a first sub-pixel;
bonding a light-emitting element on the color film substrate, so as to cause the bonding adhesive to flow from a position of the first sub-pixel of the color film substrate to a position of a second sub-pixel of the color film substrate to form a bonding material layer.

In another aspect of the present disclosure, there is provided a display device including a display substrate as described above.

### BRIEF DESCRIPTION OF THE DRAWINGS

In order to more clearly explain the technical solution in the present disclosure, the following will briefly introduce the drawings that need to be used in some embodiments of the present disclosure. It is obvious that the drawings in the following description are only the drawings of some embodiments of the present disclosure. For those skilled in the art, other drawings may also be obtained from these drawings. In addition, the drawings in the following description may be regarded as schematic diagrams and are not restrictions on the actual size of the product, the actual flow of the method, the actual timing of the signal, and so on.

FIG. 1A is a schematic plan diagram of a color film substrate according to an exemplary embodiment of the present disclosure;

FIG. 1B is a schematic plan diagram of a color film substrate according to another exemplary embodiment of the present disclosure;

FIG. 2 is a sectional diagram of a color film substrate along an AA′ line in FIG. 1A according to an exemplary embodiment of the present disclosure;

FIG. 3A schematically shows a curve relationship between a film layer thickness and brightness data of different scattering material layers obtained by test;

FIG. 3B schematically shows a sectional diagram of a barrier of a color film substrate along a BB′ line in FIG. 2 in an embodiment of the present disclosure;

FIG. 4 is a flowchart of a method of manufacturing a color film substrate according to an exemplary embodiment of the present disclosure;

FIG. 5 is a flowchart of a method of manufacturing a color film substrate according to the exemplary embodiment of the present disclosure after operation S20;

FIG. 6A to 6G are sectional views of a process of manufacturing a color filmi substrate corresponding to a method of manufacturing the color film substrate according to exemplary embodiments of the present disclosure;

FIG. 7 is a sectional view of a display substrate according to an exemplary embodiment of the present disclosure;

FIG. 8 is a flowchart of a method of manufacturing a display substrate according to an exemplary embodiment of the present disclosure;

FIG. 9A to 9C are sectional views of a process of manufacturing a display substrate corresponding to a method of manufacturing the display substrate according to exemplary embodiments of the present disclosure;

FIG. 10 is a schematic diagram of a display device according to an exemplary embodiment of the present disclosure.

It should be noted that, for the sake of clarity, in the drawings used to describe the embodiments of the present disclosure, the sizes of layers, structures or areas may be enlarged or reduced, that is, these drawings are not drawn according to the actual scale.

### DETAILED DESCRIPTION OF EMBODIMENTS

The technical solutions in some embodiments of the present disclosure will be described clearly and completely in combination with the accompanying drawings. Obviously, the described embodiments are only part of the embodiments of the present disclosure, not all of them. Based on the embodiments provided in the present disclosure, all other embodiments obtained by those skilled in the art fall within the protection scope of the present disclosure.

Unless the context otherwise requires, in the entire specification and claims, the term “comprise” and other forms such as the third person singular form “comprises” and the present participle form “comprising” are interpreted as a meaning of open and inclusive, that is, “including, but not limited to”. In the description of the specification, the terms “one embodiment”, “some embodiments”, “exemplary embodiments”, “example”, “specific example” or “some examples” are intended to indicate specific features, structures, materials or properties are included in at least one embodiment or example of the present disclosure. The schematic representation of the above terms does not necessarily refer to the same embodiment or example. In addition, the specific features, structures, materials or characteristics described may be included in any one or more embodiments or examples in any appropriate manner.

In the following, the terms “first” and “second” are only used for descriptive purposes and cannot be understood as indicating or implying relative importance or implying the number of technical features indicated. Therefore, the features defined as “first” and “second” may explicitly or implicitly include one or more of these features. In the description of embodiments of the present disclosure, unless otherwise stated, “multiple” means two or more.

When describing some embodiments, the expression of “connect” and its derivation may be used. For example, the term “electrically connected” may be used when describing some embodiments to indicate that two or more components are directly physical or electrical contacted with each other.

“At least one of A, B and C” has the same meaning as “at least one of A, B or C”, including the following combinations of A, B and C: only A, only B, only C, combination of A and B, combination of A and C, combination of B and C. and combination of A, B and C.

“A and/or B” includes the following three combinations: only A, only B, and combination of A and B.

The use of “configured to” in the present disclosure means an open and inclusive language, which does not exclude devices that are applicable to or configured to perform additional tasks or steps.

In addition, the usage of “based on” means openness and inclusiveness, because a process, step, calculation or other action “based on” one or more of the said conditions or values may be performed based on additional conditions or exceeds the said values in practice.

As used herein, “about” or “approximately” includes the stated value and an average value within an acceptable deviation range of a specific value, wherein the acceptable deviation range is determined by a person skilled in the art taking into account the measurement being discussed and the error related to the measurement of a specific amount (i.e., the limitation of the measurement system).

As used herein, “parallel”, “vertical” and “equal” include the described situation and the situation similar to the described situation, and a range of the similar situation is within an acceptable deviation range, wherein the acceptable deviation range is determined by a person skilled in the art taking into account the measurement being discussed and the error related to the measurement of a specific amount (i.e., the limitation of the measurement system). For example, “parallel” includes absolute parallel and approximate parallel, wherein the acceptable deviation range of approximate parallel may be, for example, within 5º. “Vertical” includes absolute vertical and approximate vertical, wherein the acceptable deviation range of approximate vertical may also be, for example, within 5°. “Equality” includes absolute equality and approximate equality, wherein a difference between the equal two within the acceptable deviation range of approximate equality may be, for example, less than or equal to 5% of either.

It should be understood that when a layer or element is called on another layer or substrate, it may be that the layer or element is directly on another layer or substrate, or there may be an intermediate layer between the layer or element and another layer or substrate.

In the present disclosure, “same layer” refers to film structures with a specific pattern formed by using a same film forming process and a layer structure formed by using masks through a single composition process. According to different specific patterns, the single composition process may include multiple exposure, development or etching processes, and the specific patterns in the layer structure formed may be continuous or discontinuous, and these specific patterns may also be at different heights or have different thicknesses. On the contrary, “different layer” refers to film structures with a specific pattern formed by respectively using corresponding film forming processes and a layer structure formed by using corresponding masks through a composition process. For example, “two layer structures disposed in different layers” refers to two layer structures formed under the corresponding process steps (film forming process and composition process).

Exemplary embodiments are described herein with reference to sectional views and/or plans as idealized exemplary drawings. In the attached drawing, thicknesses of layers and regions are enlarged for clarity. Therefore, it is conceivable that changes in shape relative to the drawings may occur due to, for example, manufacturing technology and/or tolerances. Therefore, the exemplary embodiments should not be interpreted as being limited to a shape of the region shown herein, but include the shape deviation caused by, for example, manufacturing. For example, the etched region shown as a rectangle will usually have a curved feature. Therefore, the regions shown in the drawings are schematic in nature, and their shapes are not intended to show the actual shapes of the regions of the device, which is not intended to limit the scope of the exemplary embodiments.

In the embodiment of the present disclosure, the term “color conversion” refers to a conversion of light color to convert a light of one color into a light of another color. For example, a light of blue may be converted into a light of red material by using different color conversion materials and a red filter layer. For another example, a light of blue may be converted into a light of green material through another color conversion material and a green filter layer.

The term “scattering” refers to adjusting an intensity of light, and adjusting the intensity of light by scattering particles set in a solvent or other materials. For example, scattering particles such as titanium dioxide are set in an acrylic resin to form a scattering material layer, so as to adjust the intensity of light.

In related technologies, due to an unreasonable structural design of a color film substrate and the limitations of the existing preparation process, when the color film substrate is bonded with a light-emitting element, a distance between a color conversion material layer of the color film substrate and a light-emitting region of the light-emitting element increases, thereby giving rise to an occurrence of color crossover.

To solve the above problems, the embodiment of the present disclosure provides a color film substrate, which includes but is not limited to a base substrate; a plurality of pixel units arranged on the base substrate, wherein each of the plurality of pixel units includes a plurality of sub-pixels. The pixel unit includes: a barrier, which is arranged on a side of the base substrate, wherein the barrier includes a first barrier arranged around a peripheral side of the pixel unit and a second barrier arranged between adjacent sub-pixels, and the plurality of sub-pixels include a first sub-pixel for color conversion and a second sub-pixel for scattering; a color conversion material layer arranged in the first sub-pixel; a scattering material layer arranged in the second sub-pixel. At least one of the first barrier and the second barrier is in a same layer as the scattering material layer, and a material of the at least one of the first barrier and the second barrier is the same as a material of the scattering material layer.

According to the embodiments of the present disclosure, by using the same material and the same process to manufacture the scattering material layer and the barrier, an amount of materials may be saved and a lithography process may be reduced. In addition, the scattering material layer is set as being made of the same material as the barrier. In a case of achieving a same display effect, a thickness of the scattering material layer is reduced to facilitate a subsequent process to provide more regions to accommodate a bonding material layer when bonding with electronic components, thus effectively reducing a risk of color crossover and improving a display effect and product yield.

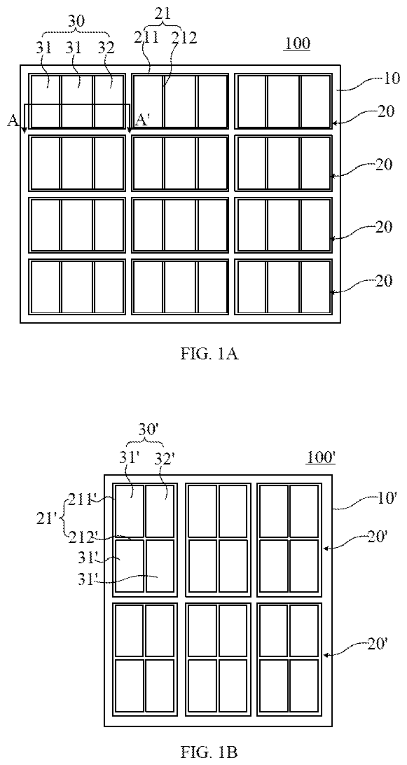

A structure of a color film substrate of the embodiment of the present disclosure will be described in detail with reference to FIG. 1.

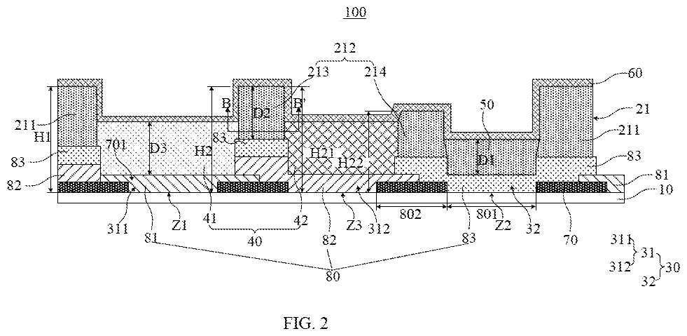

FIG. 1A is a schematic plan diagram of a color film substrate according to an exemplary embodiment of the present disclosure. FIG. 1B is a schematic plan diagram of a color film substrate according to another exemplary embodiment of the present disclosure. FIG. 2 is a sectional diagram of a color film substrate along an AA′ line in FIG. 1A according to an exemplary embodiment of the present disclosure.

In the embodiment of the present disclosure, as shown in FIGS. 1A, IB and 2, a color filmi substrate 100 (100′) includes a base substrate 10 (10′) and a plurality of pixel units 20 (20′). The plurality of pixel units 20 are arranged on the base substrate 10, and each of the plurality of pixel units 20 includes a plurality of sub-pixels. FIG. 1A schematically shows that a plurality of sub-pixels are arranged in parallel in a row in each pixel unit, and FIG. 1B schematically shows that a plurality of sub-pixels are arranged in a matrix in a plurality of rows in each pixel unit.

For example, the pixel unit 20 includes a barrier 21 (21′), which is arranged on a side of the base substrate 10. A plurality of pixel units 20 and a plurality of sub-pixels 30 are formed by the barrier 21 surrounding, and each sub-pixel 30 (30′) includes a first sub-pixel 31 (31′) and a second sub-pixel 32 (32′). The first sub-pixel 31 is used for color conversion, for example, to convert a light of blue into a light of red. The second sub-pixel 32 is used for scattering, for example, to scatter a light of blue to change an intensity of the light of blue, etc.

For example, the base substrate 10 may include, for example, a glass backplane or the like.

In the embodiment of the present disclosure, as shown in FIG. 2, a color conversion material layer 40 is arranged in a first sub-pixel 31, and a scattering material layer 50 is arranged in a second sub-pixel 32. The color conversion material layer 40 may include, for example, a first color conversion material layer 41 and a second color conversion material layer 42. Different color conversion material layers 40 may perform color conversions for different incident lights.

For example, the first color conversion material layer 41 is used for color conversion of light incident to one first sub-pixel 31, for example, to convert an incident light of blue into a light of red. The second color conversion material layer 42 is used for color conversion of light incident to another first sub-pixel 31, for example, to convert an incident light of blue into a light of green.

In the embodiment of the present disclosure, the color conversion material layer includes a Quantum Dots (QD) material.

In other optional embodiments, a number of the first sub-pixels in each pixel unit may be set according to actual needs, such as 2 or 3, etc. A number of the color conversion material layers for color conversion of different colors may correspond to the number of first sub-pixels, and may also be set according to actual design needs. For example, the color conversion material layers for color conversion of different colors may be 2 or 3, etc.

For example, the color conversion material layer may include a resin, such as an acrylic material, and a material of the first color conversion material layer may be the same as a material of the second color conversion material layer, or the material of the first color conversion material layer may be different from the material of the second color conversion material layer.

In the embodiment of the present disclosure, the scattering material layer 50 is arranged in the second sub-pixel 32. The scattering material layer 50 may adjust an intensity of the incident light.

For example, the scattering material layer 50 is used to adjust the intensity of the light incident to the second sub-pixel 32. For example, a light intensity of an incident light of blue is adjusted.

For example, the scattering material layer 50 may include, for example, a basic material and a scattering particle dispersed in the basic material. For example, the basic material includes a thermosetting resin, such as an acrylic resin, and the scattering particle includes one of titanium dioxide, silicon dioxide, organosilicon compound and polystyrene, or a combination thereof.

In the embodiment of the present disclosure, an encapsulation layer 60 is arranged on a side of the barrier 21 away from the base substrate 10. The encapsulation layer 60 covers at least one of the barrier 21, the color conversion material layer 40 and the scattering material layer 50.

The encapsulation layer 60 is used to encapsulate the barrier 21, the color conversion material layer 40 and the scattering material layer 50 to ensure that the color conversion material layer 40 and the scattering material layer 50 will not be damaged by an invasion of moisture or other substances, or produce defects that affect a color conversion effect of the color conversion material layer 40 and/or a scattering effect of the scattering material layer 50.

In the embodiment of the present disclosure, the scattering material layer 50 is in the same layer as the barrier 21, and the scattering material layer 50 is made of the same material as the barrier 21.

The scattering material layer 50 is in the same layer as the barrier 21, and the scattering material layer 50 is made of the same material as the barrier 21. It may be understood that the scattering material layer 50 and the barrier 21 are formed in the same layer by the same process in preparation, and the scattering material layer 50 and the barrier 21 are formed using one mask process to etch in photolithography, so as to effectively reduce the preparation process and improve a preparation efficiency.

The same material is used for the scattering material layer 50 and the barrier 21 in the preparation process.

The materials of the barrier 21 and the scattering material layer 50 include materials as described above, such as acrylic materials, etc.

In the embodiment of the present disclosure, the scattering material layer 50 and the barrier 21 are prepared with the same material, which may realize a simultaneous preparation of the barrier 21 and the scattering material layer 50 through one mask preparation method. On one hand, this may save material consumption, for example, may reduce other materials specially used for scattering material layer. On the other hand, this may reduce one lithography process, thus simplifying the process and improving a production efficiency.

In the embodiment of the present disclosure, an optical density (OD) of a material used to prepare the barrier 21 is in a range of 0.1/um to 0.3/um, for example, 0.15/um or 0.2/um or 0.25/um. A height of the material of the barrier is generally set to be greater than 12 um, and a critical dimension (CD value) in the process is greater than 20 um. It is calculated that a longitudinal transmittance of the material of the barrier is less than 0.4%, and a transverse transmittance is less than 0.01%. Therefore, there is no transverse or longitudinal crossover in the material of the barrier.

Transmittance refers to an ability of light to penetrate a medium after passing through the medium. The transverse transmittance refers to an ability of light to penetrate the barrier when passing through a transverse direction (parallel to a direction of a plane of the base substrate) of the barrier. The longitudinal transmittance refers to an ability of light to penetrate the barrier when passing through a longitudinal direction (perpendicular to the direction of the plane of the base substrate) of the barrier.

In this embodiment, a thickness of the scattering material layer 50 may be reduced by selecting the same material for manufacturing the scattering material layer 50 and the barrier 21. The transmittance of the material used to prepare the barrier 21 corresponds to the thickness. For example, when the scattering material layer 50 is made of the same material as the barrier 21, a film thickness of the scattering material layer 50 is set in a range of 1 um to 5 um, and the transmittance is between 10% and 60%. Thus, a film thickness of the scattering material layer 50 may be selected according to a transmission requirement and an angle of view matching.

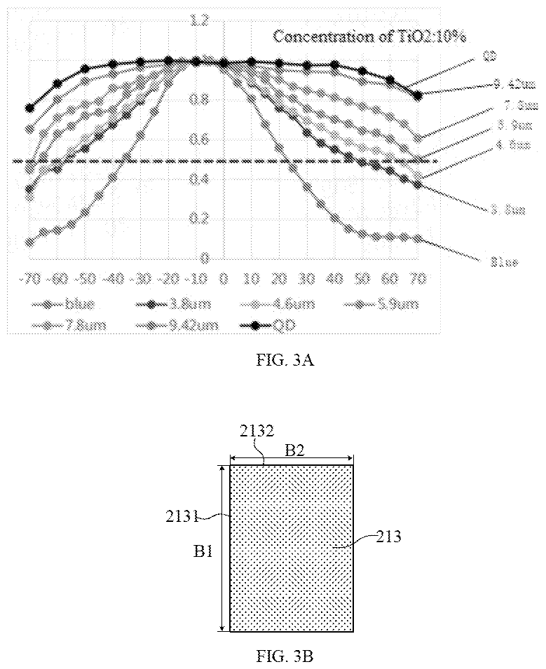

FIG. 3A schematically shows a curve relationship between a film thickness and brightness data of different scattering material layers obtained by test.

As shown in FIG. 3A, in the existing technologies, an optical density of a material of an existing scattering material layer is 0.1/um. In a test, each curve represents angle of view data, the curve identifying a film thickness in the coordinates is angle of view data of the scattering material layer under the film thickness, blue refers to an angle of view of a backlight, and QD refers to an angle of view of the color conversion material layer. A concentration of titanium dioxide represents a concentration of scattering particles in the scattering material layer. In the test, backlight brightness at different angles may be obtained by changing a position of an electric coupling device (CCD), and an angle curve may be obtained by normalizing brightness data. The flatter the curve in FIG. 3A represents the better the angle of view. The angle of view test of the scattering material layer is to place a diaphragm made of the scattering material layer on the backlight for testing. QD is to place a diaphragm made of the color conversion material layer on the backlight for testing. It may be seen from FIG. 3A that for the existing scattering material layer, when the thickness of the scattering material layer is more than 9.42 um, it has a better angle of view, but when the thickness of the scattering material layer is smaller, the obtained angle of view is poor. For example, when the thickness of the scattering material layer is 3.8 um, it has the worst angle of view in all film layer thicknesses.

Because the optical density of the scattering material layer in the relevant technology is less than 0.1 um, the scattering material layer and the barrier in the embodiment of the present disclosure use the same material, and the optical density of the scattering material layer in the embodiment of the present disclosure is in a range of 0.1 um to 0.3/um, for example, it may be 0.2/um, 0.25/um, etc. Therefore, the thickness of the scattering material layer may be reduced in the same transmittance.

In the embodiment of the present disclosure, the scattering material layer 50 and the barrier 21 are made of the same material, and the optical density of the material is within a range of 0.2/um to 0.25/um, for example, the optical density is determined to be 0.2/um. The film thickness of the scattering material layer 50 may be reduced on a premise that a scattering performance of the scattering material layer 50 is unchanged. Thus, a distance between a side of the scattering material layer away from the base substrate and a side of the base substrate is reduced, that is, a distance between the scattering material layer and the light-emitting element is increased, which is conducive to filling a capacity of a bonding adhesive or a bonding material layer for bonding the color film substrate and the light-emitting element at this position.

For example, the optical density of the scattering material layer in the existing technologies is up to 0.1/um. When the scattering material layer is made of the same material as the barrier, the optical density of a barrier material is up to 0.2/um, and the thickness of the scattering material layer made of the barrier material may be reduced from an original 9.5 um to less than 5 um, while ensuring that the angle of view performance remains unchanged.

In the embodiment of the present disclosure, a plurality of pixel units and a plurality of sub-pixels in the pixel units are formed by the barrier 21 surrounding. As shown in FIG. 1A, FIG. 1B and FIG. 2, the barrier 21 (21′) includes a first barrier 211 (211′) disposed around peripheral sides of the pixel unit 20 and a second barrier 212 (212′) disposed between adjacent sub-pixels. In a direction perpendicular to a plane of the base substrate 10, a side of the first barrier 211 away from the base substrate 10 has a first distance H1 to the base substrate 10, a side of the second barrier 212 away from the base substrate 10 has a second distance H2 to the base substrate 10, and the first distance H1 is greater than the second distance H2.

For example, the first barrier 211 surrounds peripheral sides of each pixel unit 20. As shown in FIG. 2, a sectional structure of a pixel unit in FIG. 1A is shown. The barriers surrounding the peripheral sides of each pixel unit are the first barriers 211, for example, the barriers on both sides in FIG. 2 are the first barriers 211. The barriers between the two first barriers 211 are the second barriers 212. The second barrier 212 is disposed between adjacent sub-pixels. For example, the second barrier 212 includes a third barrier 213 between the first color conversion material layer 41 and the second color conversion material layer 42, and a fourth barrier 214 between the second color conversion material layer 42 and the scattering material layer 50.

In the embodiment of the present disclosure, since there are a plurality of sub-pixels in the pixel unit, a plurality of second barriers 212 disposed between adjacent sub-pixels may be provided, and heights of the second barriers 212 between adjacent sub-pixels may be different from each other. Each second distance H2 from the side of the second barrier 212, which is between adjacent sub-pixels, away from the base substrate 10 to the base substrate 10 is less than the first distance H1 from the side of the first barrier 211 away from the base substrate 10 to the base substrate 10. That is, in the color film substrate of the embodiment of the present disclosure, all of the second distances H2 are less than the first distance H1.

For example, a side of the third barrier 213 away from the base substrate 10 has a second distance H21 to the base substrate 10, and a side of the fourth barrier 214 away from the base substrate 10 has a second distance H22 to the base substrate 10. H1 is greater than H21, and H1 is greater than H22.

In this embodiment, as shown in FIG. 2, the pixel unit 20 includes two or more first sub-pixels 31. In the direction perpendicular to the plane of the base substrate 10, a side of the second barrier 211 (between adjacent first sub-pixels 31) away from the base substrate 10 has a first sub-distance to the base substrate 10, such as H21 in FIG. 2. A side of the second barrier 211 (between adjacent first sub-pixel 31 and second sub-pixel 32) away from the base substrate 10 has a second sub-distance H22 to the base substrate 10, and the first sub-distance H21 is greater than the second sub-distance H22.

For example, the second barrier 212 includes the third barrier 213 and the fourth barrier 214. The third barrier 213 is disposed between two adjacent first sub-pixels 31. The fourth barrier 214 is disposed between adjacent first sub-pixel 31 and second sub-pixel 32. It may be seen from the above that the first sub-distance H21 is from the third barrier 213 to the base substrate 10, and the second sub-distance H22 is from the fourth barrier 214 to the base substrate 10. Therefore, the first sub-distance H21 of the third barrier 213 in the second barrier between adjacent first sub-pixels 31 is greater than or equal to the second sub-distance H22 of the fourth barrier 214 in the second barrier between adjacent first sub-pixel 31 and second sub-pixel 32.

According to the embodiment of the present disclosure, as described above, by using the same material and the same process to make the scattering material layer and the barrier material, the thickness of the scattering material layer may be reduced while ensuring the same display effect, so as to provide a large space for the bonding material layer in the subsequent bonding of light-emitting elements, and prevent the material of the bonding material layer from overflowing in bonding.

In the embodiment of the present disclosure, a size of at least one boundary of a section of at least one of the first barrier and the second barrier is greater than a size of the thickness of the scattering material layer, and the section is parallel to a direction of a plane on which the base substrate is located.

As shown in FIG. 3B, a sectional diagram of a barrier of a color film substrate along a BB′ line in FIG. 2 in an embodiment of the present disclosure is schematically shown.

For example, as shown in FIG. 3B, the barrier 21 includes the first barrier 211 and the second barrier 212, and the second barrier 212 includes the third barrier 213 and the fourth barrier 214. For example, the section diagram of the third barrier 213 along the BB′ line is shown in FIG. 3B. The section of the first barrier along BB′ line and the section of the second barrier along BB′ line are parallel to the plane of the base substrate 10. The boundary of the section of the third barrier 213 along BB′ line includes a first boundary 2131 and a second boundary 2132. The size of a boundary of the first boundary 2131 represents a length B1 of the first boundary 2131, and a size of a boundary of the second boundary 2132 represents a length B2 of the second boundary 2132.

In other optional embodiments, the sizes of the first and/or second barrier along the section parallel to the plane of the base substrate may be determined according to the example described above.

The thickness of the scattering material layer 50 is shown as D1 in FIG. 2.

According to the embodiment of the present disclosure, both a size B1 of the first boundary 2131 and a size B2 of the second boundary 2132 are greater than the thickness D1 of the scattering material layer 50. This may ensure that the scattering material layer 50 has a good light scattering effect and does not affect the transmittance. Besides, this may ensure that the barrier has a good light blocking effect, avoid a color crossover between adjacent sub-pixels, and improve the display effect.

In the embodiment of the present disclosure, the size of at least one boundary of the section of at least one of the first barrier and the second barrier is greater than or equal to the thickness of the first barrier and/or the second barrier in the direction perpendicular to the plane of the base substrate, and the section is parallel to the direction of the plane of the base substrate.

As shown in FIG. 2 and FIG. 3B, the size B1 of the first boundary 2131 and/or the size B2 of the second boundary 2132 of the section of the third barrier 213 in the second barrier 212 is greater than or equal to a thickness D2 of the third barrier in the direction perpendicular to the plane of the base substrate.

In other embodiments, the boundary of the section of the barrier (including the first barrier and the second barrier) may be determined according to the above example.

According to the embodiment of the present disclosure, the boundary of the section parallel to the plane direction of the base substrate is determined to be greater than or equal to the thickness of the barrier in the direction perpendicular to the plane direction of the base substrate, so as to ensure that the barrier has the good light blocking effect and prevent the color crossover problem between adjacent sub-pixels.

In the embodiment of the present disclosure, the thickness of the scattering material layer is less than the thickness of the color conversion material layer in the direction perpendicular to the plane of the base substrate.

For example, as shown in FIG. 2, the color conversion material layer 40 has a thickness D3 in the direction perpendicular to the plane of the base substrate, and the scattering material layer 50 has a thickness D1 in the direction perpendicular to the plane of the base substrate. D1 is smaller than D3, thus ensuring that the color film substrate may accommodate more bonding materials at a position of the scattering material layer 50 relative to a position of the color conversion material layer 40.

In the embodiment of the present disclosure, as shown in FIG. 2, the color film substrate 100 also includes a black matrix 70 and a color film layer 80.

The black matrix 70 is arranged between the base substrate 10 and the barrier 21. The black matrix 70 includes a plurality of openings 701, which correspond to a plurality of sub-pixels. The color film layer 80 covers the black matrix 70 and the base substrate 10. The color film layer 80 includes a first color film part 801 and a second color film part 802. An orthographic projection of the first color film part 801 on the base substrate 10 is located in the opening 701. An orthographic projection of the second color film part 802 on the base substrate 10 is located in an orthographic projection of the black matrix 70 on the base substrate.

For example, the color film layer 80 covers a side of the black matrix 70 away from the base substrate, and the color film covers the base substrate in a region of the opening 701. The first color film part 801 is arranged in the opening 701 formed by the black matrix 70, and the second color film part 802 covers a region on which the black matrix 70 is located.

For example, the black matrix 70 may, for example, block the light, so that a light passing through the color film layer 80 enters a target region through the opening 701 formed by the black matrix 70. The black matrix 70 may be formed by an ink-jet method. The black matrix 70 may be formed by the ink-jet method without performing additional mask process and/or lithography process, which may simplify a manufacturing process and reduce a manufacturing cost.

For example, after forming the black matrix 70, the color filmi layer 80 is disposed, including disposing the first color film part 801 and the second color film part 802. Color films of the second color film part 802 may be the same or different from each other, or may be partially the same. For example, the second color film part 802 includes color films of multiple colors.

In the embodiment of the present disclosure, as shown in FIG. 2, the plurality of sub-pixels include a first color sub-pixel Z1, a second color sub-pixel Z2 and a third color sub-pixel Z3, the first color sub-pixel Z1 and the third color sub-pixel Z3 are located in the first sub-pixel 31, and the second color sub-pixel Z2 is located in the second sub-pixel 32.

For example, the first sub-color pixel Z1 is red sub-pixel R (Red), the third sub-color pixel Z3 is green sub-pixel G (Green), the second sub-color pixel Z2 is blue sub-pixel B (Blue), the red sub-pixel R and the green sub-pixel G are located in the first sub-pixel 31, and the blue sub-pixel B is located in the second sub-pixel 32.

For example, the first sub-pixel 31 includes a first region 311 corresponding to the first color conversion material layer 41, and the first sub-pixel 31 also includes a second region 312 corresponding to the second color conversion material layer 42. The red sub-pixel R is located in the first region 311, and the green sub-pixel G is located in the second region 312.

In the optional embodiment of the present disclosure, the plurality of sub-pixels may also include sub-pixels of other colors, such as white sub-pixels. The disposing positions of the plurality of sub-pixels may be adjusted according to the actual needs to meet the requirements of different light-emitting elements. For example, a color of the second color sub-pixel located in the second sub-pixel is consistent with a light-emitting color of the light-emitting element, and colors of the first color sub-pixel and the third color sub-pixel located in the first sub-pixel are inconsistent with the light-emitting color of the light-emitting element.

According to the embodiment of the present disclosure, the color of the second color sub-pixel located in the second sub-pixel is consistent with the light-emitting color of the light-emitting element, that is, a scattering material layer needs to be disposed in a second pixel region. A manufacturing material of the scattering material layer is the same as the manufacturing material of the barrier, and the scattering material layer and the barrier are formed by the same manufacturing process, thus reducing the manufacturing process of the color film substrate, and reducing the thickness of the scattering material layer, so as to provide, for the subsequent bonding of the light-emitting element on the color film substrate, more spaces for the bonding material layer, improve the display effect, and reduce an abnormal light emission.

In the embodiment of the present disclosure, the first color film part 801 includes a first color filter layer 81 disposed in the first sub-color pixel, such as a red filter layer disposed in the red sub-pixel R; a third color filter layer 82 disposed in the third color sub-pixel, for example, a green filter layer disposed in the green sub-pixel G; and a second color filter layer 83 disposed in the second color sub-pixel, such as a blue filter layer disposed in the blue sub-pixel B.

For example, the red filter layer makes the light into the target region red, the green filter layer makes the light into the target region green, and the blue filter layer makes the light into the target region blue.

In other optional embodiments of the present disclosure, the first color film part may also dispose other color filter layers as required to meet the requirements of filtering for different colors.

In the embodiment of the present disclosure, the second color film part 802 comprises at least two stacked filter layers. The second color film part 802 may be a region in which filter layers of different colors are intersected. When the second color film part 802 forms a color film layer, the filter layers of different colors are overlapped or stacked due to different process sequences, thereby forming a color film layer with multiple color filter layers.

For example, as shown in FIG. 2, two filter layers are included between the first barrier 21 and the black matrix 70. For example, in FIG. 2, the green color filter layer and the blue color filter layer are stacked and included between the first barrier 21 close to the red sub-pixel R and the black matrix 70. In FIG. 2, the red filter layer and the blue filter layer are overlapped with each other and included between the first barrier 21 close to the blue sub-pixel B and the black matrix.

For example, as shown in FIG. 2, the red filter layer, the green filter layer and the blue filter layer are stacked and overlapped and included between the third barrier 213 and the black matrix 70. A part of the red filter layer is covered by the green filter layer, and the blue filter layer is stacked on the green filter layer.

For example, as shown in FIG. 2, the green filter layer and the blue filter layer are overlapped with each other and included between the fourth barrier 214 and the black matrix 70, and a part of the blue filter layer is covered on the green filter layer.

In the embodiment of the present disclosure, the thickness of the second color film part 802 is greater than the thickness of the first color film part 801 in the direction perpendicular to the plane of the base substrate.

The second color film part 802 includes at least two filter layers, and the first color film part 801 includes one filter layer. By setting the thickness of the second color film part 802 to be greater than the thickness of the first color film part 801, a preparation difficulty of a barrier of high thickness may be reduced.

In the embodiment of the present disclosure, according to a coating process, there is a phenomenon of morphology following, that is, in a coating region of the coating, when sides of the coating have different heights, in the coating process, coating changes and is prone to appear bulges with a change of morphology.

For example, as shown in FIG. 2, in a process of forming different color filter layers, there are different coating sequences. For example, the color film layer 80 includes the red filter layer 81, the green filter layer 82 and the blue filter layer 83. When forming the color film layer 80, first the red filter layer 81 is coated, then the green filter layer 82 is coated, and finally the blue filter layer 83 is coated.

On a side of the third barrier 213 close to the base substrate 10 and at a position of the second color film part 802, when the first color filter layer 81, such as the red filter layer, is coated, the red filter layer covers a part of the black matrix 70. And then the third color filter layer 82, such as the green filter layer, is formed. The green filter layer overlaps with the red filter layer at the position of the second color film part 802. Because of an appearance following phenomenon described above, at a position of the second color film part 802 where the third barrier 213 is located, the second color filter layer 83 is formed on a side of the first color filter layer 81 away from the base substrate, for example, a certain thickness of green filter layer is formed on a side of the red filter layer away from the base substrate. When coating the filter layer of other colors, a corresponding color filter layer is formed at a position of the second color film part 802, thus the thickness of the color film layer at the position of the second color film part 802 is greater than the thickness of the color film layer at the position of the first color film part 801.

According to the embodiment of the present disclosure, the material and process for forming the scattering material layer and the barrier are the same. Under the preparation conditions and process, there is a limit condition for the formed height difference. For example, when the thickness of the barrier material is thick, it may not be formed, or the preparation process is difficult. In this regard, the thickness of the color film layer formed on the second color film part is greater than the thickness of the color film layer formed on the first color film part, so that the embodiment of the present disclosure may, by using the appearance following phenomenon of the coating process, effectively reduce the thickness of the barrier formed on the side of the color film layer away from the base substrate, and reduce the technical difficulty of preparing different height difference graphics on the same layer of the barrier and the scattering material layer.

In an embodiment of the present disclosure, the formation of the scattering material layer and the barrier may use a positive glue scheme, and the halftone mask may be used to realize a one-time preparation of the barrier and the scattering material layer with different thicknesses.

In another embodiment of the present disclosure, a negative glue scheme is used. When exposure energy is insufficient, a film thickness is positively correlated with exposure amount. According to this principle, the one-time preparation of different thickness of barrier and scattering material layers may be realized by using halftone mask. For example, main photospacer and sub-photospacer in existing LCD products are prepared by a halftone mask process.

In another embodiment of the present disclosure, in a process of forming the scattering material layer and the barrier, the negative glue scheme is used. It is difficult to realize a high segment difference process with a negative glue in the same layer. The scattering material layer may be prepared by using a separate mask.

In another embodiment of the present disclosure, the negative glue scheme may be used to overlap the positions with which the film layers of different colors of the color film is contacted, and a height difference of the scattering material layer and the barrier may be achieved by using a segment difference of an overlap of the color film.

In the embodiment of the present disclosure, a display using the color film substrate described above may include but not limited to QD-OLED, QD-LCD and QD-LED, etc.

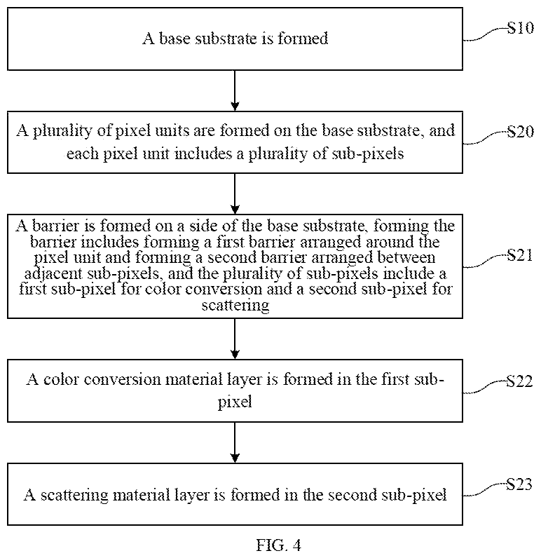

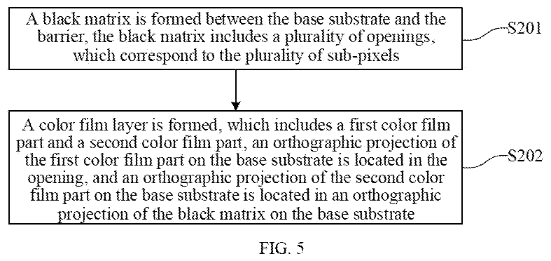

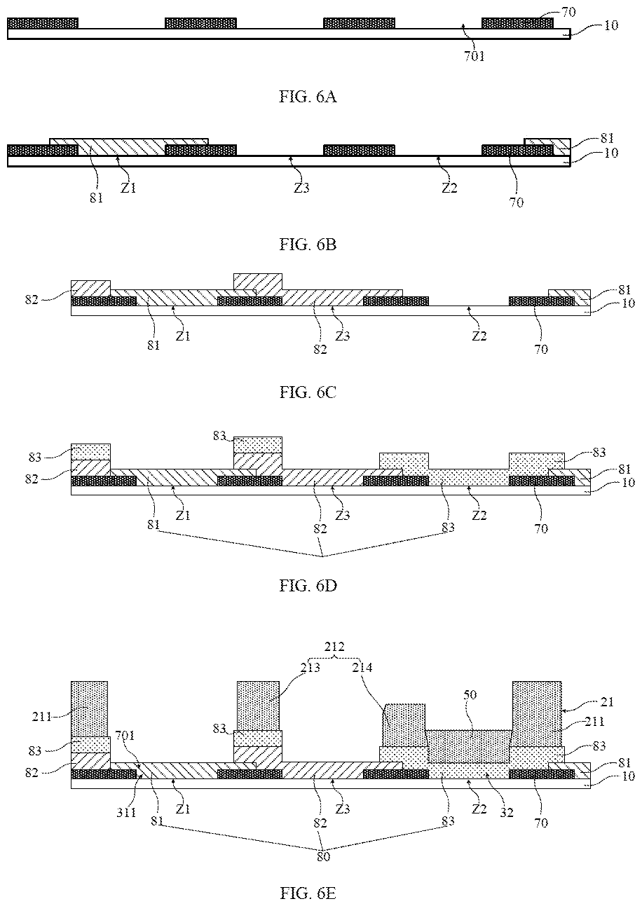

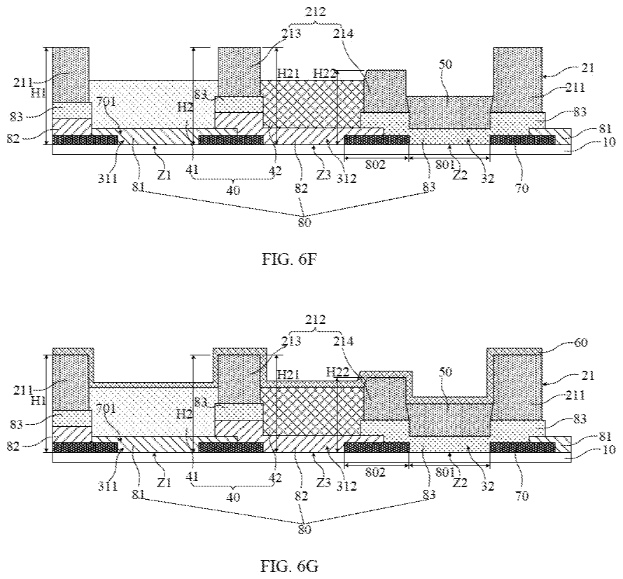

FIG. 4 is a flowchart of a method of manufacturing a color film substrate according to an exemplary embodiment of the present disclosure. FIG. 5 is a flowchart of a method of manufacturing a color film substrate according to the exemplary embodiment of the present disclosure after operation S20. FIGS. 6A to 6G are sectional views of a process of manufacturing a color film substrate corresponding to a method of manufacturing the color film substrate according to the exemplary embodiments of the present disclosure.

The method of manufacturing a color film substrate in the embodiment of the present disclosure will be described in detail in combination with FIGS. 4 to 6G.

Some embodiments of the present disclosure also provide a method of manufacturing a color film substrate, as shown in FIGS. 4 to 6G. The manufacturing method includes operations S10 to S23.

In operation S10, a base substrate is formed. As shown in FIG. 6A, a base substrate 10 is formed.

In operation S20, a plurality of pixel units are formed on the base substrate, and each pixel unit includes a plurality of sub-pixels.

In the embodiment of the present disclosure, operation S20 may be followed by operations S21 to S24. That is, forming pixel unit includes operations S21 to S23.

In operation S21, a barrier 21 is formed on a side of the base substrate 10. A plurality of pixel units and a plurality of sub-pixels are formed by surrounding the barrier 21 in the pixel units. The plurality of sub-pixels include a first sub-pixel 31 for color conversion and a second sub-pixel 32 for scattering.

For example, as shown in FIG. 6E, a barrier 21 is formed, wherein the barrier 21 includes a first barrier 211 arranged around the pixel unit and a second barrier 212 arranged between adjacent sub-pixels. The second barrier 212 includes a barrier between a first sub-color pixel and a third color sub-pixel, and a barrier between the first color sub-pixel and a second color sub-pixel, for example, a third barrier 213 between a red sub-pixel R and a green sub-pixel G, and a fourth barrier 214 between the green sub-pixel G and a blue sub-pixel B.

In operation S22, a color conversion material layer 40 is formed in the first sub-pixel 31.

For example, as shown in FIG. 6F, the color conversion material layer 40 is formed, including a first color conversion material layer 41 located in the red sub-pixel R and a second color conversion material layer 42 located in the green sub-pixel G.

In operation S23, a scattering material layer 50 is formed in the second sub-pixel 32. The scattering material layer and the barrier are formed by a one-time patterning process.

For example, as shown in FIG. 6E, the scattering material layer 50 is formed while the barrier 21 is formed.

In the embodiment of the present disclosure, a sequence between operation S23 and operation S22 may be to execute operation S23 before operation S22. For example, in operation S21, when the barrier 21 is formed on a side of the base substrate 10, operation S23 is executed at the same time to form a scattering material layer 50 in the second sub-pixel 32. The scattering material layer 50 and the barrier 21 use the same process and are manufactured by the same mask. A material of the scattering material layer is the same as a material of the barrier.

According to the embodiment of the present disclosure, a manufacturing process of the color film substrate may be reduced, a consumption of materials may be saved, and a manufacturing cost may be reduced. Besides, the scattering material layer and the barrier may be made of the same material to reduce the thickness of the scattering material layer while maintaining the display effect of the color film substrate. When a subsequent color film substrate is bonded with a light-emitting element, more space is provided for a bonding material layer, so as to prevent an overflowing of bonding material layer in bonding.

In other optional embodiments, operation S22 may be performed before operation S23.

In the embodiment of the present disclosure, after a formation of the color conversion material layer, an encapsulation layer 60 is also formed on a side of the barrier 21 away from the base substrate, and the encapsulation layer 60 covers the barrier 21, the color conversion material layer 40 and the scattering material layer 50. The barrier, the color conversion material layer and the scattering material layer are encapsulated by the encapsulation layer to ensure that the color conversion material layer 40 and the scattering material layer 50 will not be damaged by an invasion of moisture or other substances, or produce defects that affect a color conversion effect of the color conversion material layer 40 and/or a scattering effect of the scattering material layer 50.

For example, as shown in FIG. 6G, the encapsulation layer 60 is formed on a side of the barrier 21, the color conversion material layer 40 and the scattering material layer 50 away from the base substrate.

In the embodiment of the present disclosure, in operation S21, forming the barrier 21 on a side of the base substrate 10 includes forming a first barrier 211 arranged around a peripheral side of the pixel unit and forming a second barrier 212 arranged between adjacent sub-pixels. In a direction perpendicular to a plane of the base substrate, a side of the first barrier 211 away from the base substrate has a first distance H1 to the base substrate, a side of the second barrier 212 away from the base substrate has a second distance H2 to the base substrate, and the first distance H1 is greater than the second distance H2.

In the embodiment of the present disclosure, when the second barrier is formed, a side of the second barrier between adjacent first sub-pixels away from the base substrate has a first sub-distance to the base substrate, a side of the second barrier between adjacent first sub-pixel and second sub-pixel away from the base substrate has a second sub-distance to the base substrate, and the first sub-distance is greater than or equal to the second sub-distance.

In the embodiment of the present disclosure, as shown in FIGS. 5 to 6G, operations S201 to S202 are also included after operation S20 and before operation S21.

In operation S201, a black matrix 70 is formed between the base substrate 10 and the barrier 21. The black matrix 70 includes a plurality of openings 701, which correspond to the plurality of sub-pixels. As shown in FIG. 6A, a black matrix 70 is formed on the base substrate 10, and the black matrix has a plurality of openings 701.

In operation S202, a color film layer 80 is formed, which includes a first color film part 801 and a second color film part 802, wherein an orthographic projection of the first color film part 801 on the base substrate is located in the opening 701; an orthographic projection of the second color film part 802 on the base substrate is located in an orthographic projection of the black matrix 70 on the base substrate 10.

In the embodiment of the present disclosure, a thickness of the formed second color film part is greater than a thickness of the formed first color film part in the direction perpendicular to the plane of the base substrate.

For example, as shown in FIGS. 6B to 6D, first, as shown in FIG. 6B, a first color filter layer 81 is formed in a first sub-pixel Z1, for example, a red light filter layer is formed in the red sub-pixel R. Then, as shown in FIG. 6C, a third color filter layer 82 is formed in a third sub-pixel Z3, for example, a green filter layer 82 is formed in the green sub-pixel G. As shown in FIG. 6D, a second color filter layer 83 is formed in the second sub-pixel Z2, a blue filter layer is formed in the blue sub-pixel B. Finally, a color film layer 80 including the first color filter layer 81, the third color filter layer 82 and the second color filter layer 83 is formed.

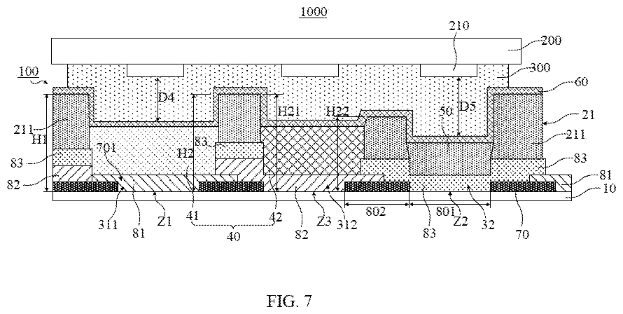

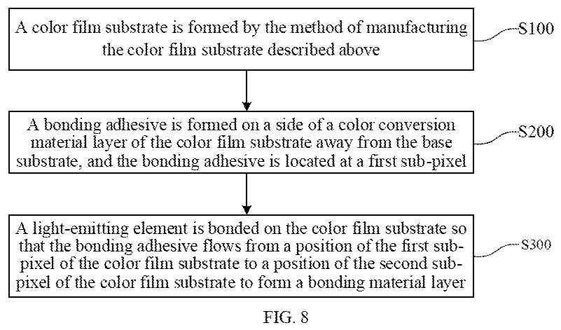

FIG. 7 is a sectional view of a display substrate according to an exemplary embodiment of the present disclosure.

Some embodiments of the present disclosure also provide a display substrate. As shown in FIG. 7, a display substrate 1000 includes a color film substrate 100 as described above and a light-emitting element 200 arranged on a side of the color film substrate away from the base substrate. The light-emitting element 200 is bonded with the color film substrate 100 through a bonding material layer 300.

For example, the light-emitting element 200 includes a light-emitting unit 210 for emitting light of a preset color. For example, the light-emitting unit 210 of this embodiment is used to emit blue light. In other optional embodiments, the light-emitting unit may be used to emit light of other colors, such as red light, etc.

In the embodiment of the present disclosure, the light-emitting element 200 includes, for example, MicroLED or OLED.

In the embodiment of the present disclosure, as shown in FIG. 7, a bonding material layer has a first thickness D4 between a color conversion material layer of the color film substrate and the light-emitting element, the bonding material layer has a second thickness D5 between a scattering material layer of the color film substrate and the light-emitting element, and the first thickness D4 is less than the second thickness D5.

According to the embodiment of the present disclosure, the second thickness D5 is less than the first thickness D4. When the bonding material layer is formed, a larger space may be provided between the scattering material layer and the light-emitting element to accommodate more bonding materials, and prevent the problem of overflowing the bonding material when the light-emitting element 200 is bonded with the color film substrate 100.

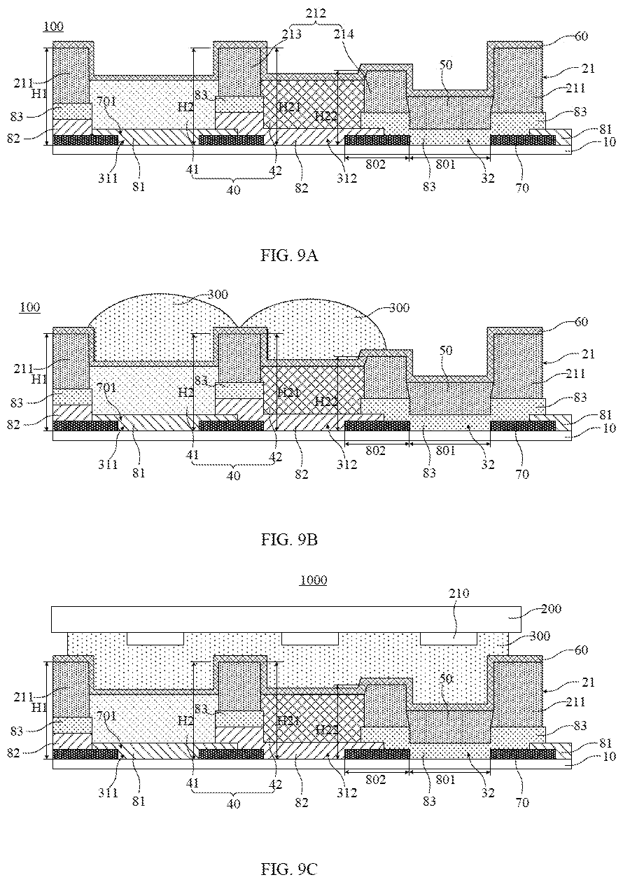

FIG. 8 is a flowchart of a method of manufacturing a display substrate according to an exemplary embodiment of the present disclosure. FIGS. 9A to 9C are sectional views of a process of manufacturing a display substrate corresponding to the method of manufacturing the display substrate according to the exemplary embodiment of the present disclosure.

Some embodiments of the present disclosure also provide a method of manufacturing a display substrate. As shown in FIGS. 8 to 9C, a specific process includes operation S100 to operation S300.

In operation S100, a color film substrate is formed by the method of manufacturing the color film substrate described above, and the formed color film substrate is shown in FIG. 9A.

In operation S200, a bonding adhesive is formed on a side of a color conversion material layer of the color film substrate away from the base substrate, and the bonding adhesive is located in a first sub-pixel, as shown in FIG. 9B.

In the embodiment of the present disclosure, the formed bonding adhesive is located in the first pixel, that is, an orthographic projection of the formed bonding adhesive on the base substrate overlaps with an orthographic projection of the color conversion material layer on the base substrate, and the orthographic projection of the formed bonding adhesive on the base substrate does not overlap with an orthographic projection of the scattering material layer on the base substrate.

In operation S300, a light-emitting element is bonded on the color film substrate so that the bonding adhesive flows from a position of the first sub-pixel of the color film substrate to a position of the second sub-pixel of the color film substrate to form a bonding material layer, as shown in FIG. 9C.

In the embodiment of the present disclosure, the bonding adhesive is located at the position of the first sub-pixel of the color film substrate. In the bonding, the bonding adhesive is driven by external pressure to flow from a position of the first sub-pixel of the color film substrate towards a position of the second sub-pixel of the color film substrate, a region between the scattering material layer and the light-emitting element is filled, and finally the bonding material layer is formed.

For example, the bonding adhesive 300 is formed on a side of the color film substrate 100 away from the base substrate. For example, the bonding adhesive 300 is coated on sides of the first color material transfer layer 41 and the second color material transfer layer 42 away from the base substrate by dispensing or screen printing. A side of the scattering material layer 50 away from the base substrate is not provided with the bonding material layer 300, as shown in FIG. 9B.

When the light-emitting element 200 is bonded with the color film substrate, because the bonding material layer 300 is not provided on the side of the scattering material layer 50 far away from the base substrate, and because heights of the barriers are different from each other, the bonding material layer flows from sides of the first color to material layer 41 and the second color to material layer 42 away from the base substrate to the side of the scattering material layer 50 away from the base substrate, so as to effectively prevent the overflow of the bonding material layer 300 in bonding.

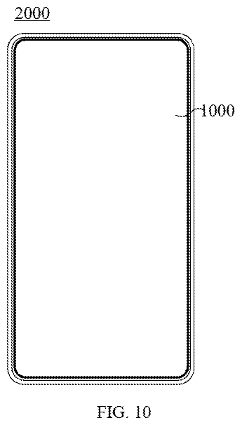

FIG. 10 is a schematic diagram of a display device according to an exemplary embodiment of the present disclosure.

As shown in FIG. 10, a display device 2000 includes the display substrate 1000 described above.

The beneficial effects achieved by the display device 2000 in the above embodiments of the present disclosure are the same as those achieved by the display substrate 1000 and the color film substrate 100.

The above display device 2000 may be any device that displays images regardless of motion (for example, video) or fixed (for example, still images) and regardless of text or image. More specifically, it is expected that the embodiments may be implemented in or associated with a variety of electronic devices, such as (but not limited to) mobile phones, wireless devices, personal data assistants (PDAs), handheld or portable computers, GPS receivers/navigators, cameras, MP4 video players, video cameras, game consoles, watches, clocks, calculators, television monitors, flat panel displays, computer monitors, car displays (e.g., odometer display, etc.), navigators, cockpit controllers and/or displays, displays of camera view (e.g., display of rear-view camera in vehicle), electronic photos, electronic billboards or indicators, projectors, architectural structures, packaging and aesthetic structures (e.g., display of image of a piece of jewelry), etc.

Although some embodiments of the general concept of the present disclosure have been illustrated and explained, those skilled in the art will understand that these embodiments may be changed without departing from the principles and spirit of the general concept of the present invention. The scope of the present disclosure is limited by the claims and their equivalents.

1. A color film substrate, comprising:
a base substrate;
a plurality of pixel units arranged on the base substrate, wherein each of the plurality of pixel units comprises a plurality of sub-pixels;
wherein the pixel unit comprises:
a barrier arranged on a side of the base substrate, wherein the barrier comprises a first barrier arranged around a peripheral side of the pixel unit and a second barrier arranged between adjacent sub-pixels, and the plurality of sub-pixels comprise a first sub-pixel for color conversion and a second sub-pixel for scattering;
a color conversion material layer arranged in the first sub-pixel; and
a scattering material layer arranged in the second sub-pixel;
wherein at least one of the first barrier and the second barrier is in a same layer as the scattering material layer, and a material of the at least one of the first barrier and the second barrier is the same as a material of the scattering material layer.

2. The color film substrate of claim 1, wherein
in a direction perpendicular to a direction of a plane on which the base substrate is located, a side of the first barrier away from the base substrate has a first distance to the base substrate, a side of the second barrier away from the base substrate has a second distance to the base substrate, and the first distance is greater than the second distance.

3. The color film substrate of claim 2, wherein the pixel unit comprises two or more first sub-pixels,
in the direction perpendicular to the direction of the plane on which the base substrate is located, a side of the second barrier between adjacent first sub-pixels away from the base substrate has a first sub-distance to the base substrate, and a side of the second barrier between adjacent first sub-pixel and second sub-pixel away from the base substrate has a second sub-distance to the base substrate,
wherein the first sub-distance is greater than the second sub-distance.

4. The color film substrate of claim 1, wherein
a size of at least one boundary of a section of at least one of the first barrier and the second barrier is greater than a size of a thickness of the scattering material layer, and the section is parallel to a direction of a plane on which the base substrate is located.

5. The color film substrate of claim 1, wherein
a size of at least one boundary of a section of at least one of the first barrier and the second barrier is greater than or equal to a thickness of the first barrier and/or the second barrier in a direction perpendicular to a direction of a plane on which the base substrate is located, and the section is parallel to the direction of the plane on which the base substrate is located.

6. The color film substrate of claim 1, wherein a thickness of the scattering material layer is less than a thickness of the color conversion material layer in a direction perpendicular to a direction of a plane on which the base substrate is located.

7. The color film substrate of claim 1, further comprising:
a black matrix arranged between the base substrate and the barrier, and the black matrix comprising a plurality of openings corresponding to the plurality of sub-pixels;
a color film layer comprising a first color film part and a second color film part;
wherein an orthographic projection of the first color film part on the base substrate is located in the opening;
an orthographic projection of the second color film part on the base substrate is located within an orthographic projection of the black matrix on the base substrate.

8. The color film substrate of claim 7, wherein the first sub-pixel comprises a first color sub-pixel and a third color sub-pixel, the second sub-pixel comprises a second color sub-pixel, the first color sub-pixel and the third color sub-pixel are located in the first sub-pixel, and the second color sub-pixel is located in the second sub-pixel.

9. The color film substrate of claim 8, wherein the first color film part comprises:
a first color filter layer disposed in the first color sub-pixel and a third color filter layer disposed in the third color sub-pixel.

10. The color film substrate of claim 9, wherein the first color film part comprises:
a second color filter layer disposed in the second color sub-pixel.

11. The color film substrate of claim 7, wherein a thickness of the second color film part is greater than a thickness of the first color film part in a direction perpendicular to a direction of a plane on which the base substrate is located.

12. The color film substrate of claim 7, wherein the second color film part comprises at least two stacked filter layers.

13. The color film substrate of claim 1, wherein an optical density of a material of the barrier is in a range of 0.1/um to 0.3/um.

14. The color film substrate of claim 1, wherein the color conversion material layer comprises a quantum dot material, the color film substrate further comprises an encapsulation layer arranged on a side of the barrier away from the base substrate, and the encapsulation layer covering at least one of the barrier, the color conversion material layer and the scattering material layer.

15. (canceled)

16. A display substrate, comprising:
the color film substrate of claim 1;
a light-emitting element arranged on a side of the color film substrate away from the base substrate; and
a bonding material layer arranged between the color film substrate and the light-emitting element.

17. The display substrate of claim 16, wherein the light-emitting element comprises MicroLED or OLED.

18. The display substrate of claim 16, wherein
the bonding material layer has a first thickness between a color conversion material layer of the color film substrate and the light-emitting element,
the bonding material layer has a second thickness between a scattering material layer of the color film substrate and the light-emitting element, and
the first thickness is less than the second thickness.

19. A method of manufacturing a color film substrate, comprising:
forming a base substrate; and
forming a plurality of pixel units on the base substrate, wherein each of the plurality of pixel units comprises a plurality of sub-pixels;
wherein forming the pixel unit comprises:
forming a barrier on a side of the base substrate, wherein forming the barrier comprises forming a first barrier arranged around a peripheral side of the pixel unit and forming a second barrier arranged between adjacent sub-pixels, and the plurality of sub-pixels comprise a first sub-pixel for color conversion and a second sub-pixel for scattering;
forming a color conversion material layer in the first sub-pixel;
forming a scattering material layer in the second sub-pixel;
wherein the scattering material layer and the barrier are formed by a one-time patterning process.

20. A method of manufacturing a display substrate, comprising:
forming a color film substrate according to the method of manufacturing a color film substrate of claim 19;
forming a bonding adhesive on a side of a color conversion material layer of the color film substrate away from a base substrate, wherein the bonding adhesive is located in a first sub-pixel; and
bonding a light-emitting element on the color film substrate, so as to cause the bonding adhesive to flow from a position of the first sub-pixel of the color film substrate to a position of a second sub-pixel of the color film substrate to form a bonding material layer.

21. A display device comprising the display substrate of claim 16.
